(19) United States
(12) Patent Application Publication
(10) Pub. No.: US 2024/0155824 A1
(43) Pub. Date: May 9, 2024

(54) SEMICONDUCTOR DEVICE MANUFACTURING METHOD AND SEMICONDUCTOR DEVICE

(71) Applicant: Tokyo Electron Limited, Tokyo (JP)

(72) Inventors: Masahiro IKEJIRI, Nirasaki City (JP); Masaki TERABAYASHI, Nirasaki City (JP); Koji MAEKAWA, Nirasaki City (JP); Koji AKIYAMA, Nirasaki City (JP)

(21) Appl. No.: 18/500,170

(22) Filed: Nov. 2, 2023

(30) Foreign Application Priority Data
Nov. 7, 2022 (JP) 2022-177935

(51) Int. Cl. H10B 12/00

(52) U.S. Cl. CPC H10B 12/03; H10B 12/30

(57) ABSTRACT

A method of manufacturing a semiconductor device includes: forming a lower electrode made of a Ti-containing film on a substrate; forming a niobium oxide film on the lower electrode; forming an oxide-based high-dielectric-constant film on the niobium oxide film; forming an upper electrode on the oxide-based high-dielectric-constant film; and performing annealing, wherein, through the forming of the oxide-based high-dielectric-constant film, the forming of the upper electrode, and the performing of the annealing, the niobium oxide film is modified into a low-oxidation-number niobium oxide film that is primarily made of a niobium oxide with an oxidation number lower than Nb₂O₅.

### CROSS-REFERENCE TO RELATED APPLICATION

This application is based upon and claims the benefit of priority from Japanese Patent Application No. 2022-177935, filed on Nov. 7, 2022, the entire contents of which are incorporated herein by reference.

### TECHNICAL FIELD

The present disclosure relates to a semiconductor device manufacturing method and a semiconductor device.

### BACKGROUND

Capacitors used in DRAM or the like are formed in such a way that a lower electrode, a dielectric film, and an upper electrode are formed on a substrate in this order. Patent Document 1 discloses a capacitor using an oxide-based high-dielectric-constant film, such as a zirconium oxide, as the dielectric film.

In addition, Patent Document 2 discloses a capacitor including a first dielectric film containing a tantalum oxide or niobium oxide, a second dielectric film provided between the lower electrode and the first dielectric film, and a third dielectric film provided between the first dielectric film and the upper electrode. Further, Patent Document 2 discloses that a zirconium oxide or the like is used as the second and third dielectric films.

### PRIOR ART DOCUMENTS

### Patent Documents

Patent Document 1: Japanese Laid-Open Patent Publication No. 2001-152339

Patent Document 2: Japanese Laid-Open Patent Publication No. 2004-266009

### SUMMARY

According to one embodiment of the present disclosure, a method of manufacturing a semiconductor device includes: forming a lower electrode made of a Ti-containing film on a substrate; forming a niobium oxide film on the lower electrode; forming an oxide-based high-dielectric-constant film on the niobium oxide film; forming an upper electrode on the oxide-based high-dielectric-constant film; and performing annealing, wherein, through the forming of the oxide-based high-dielectric-constant film, the forming of the upper electrode, and the performing of the annealing, the niobium oxide film is modified into a low-oxidation-number niobium oxide film that is primarily made of a niobium oxide with an oxidation number lower than Nb₂O₅.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a semiconductor device manufacturing method according to an embodiment.

FIGS. 2A to 2E are cross-sectional process views illustrating the semiconductor device manufacturing method according to the embodiment.

FIG. 3 is a view illustrating results of CET and leakage current for Sample 1 obtained by the method of the embodiment and Comparative Sample 2.

FIG. 4 is a view illustrating a relationship between a film thickness of a NbOₓ film and the CET as well as the leakage current.

FIG. 5 is a view illustrating results of the CET and the leakage current for Samples 11 to 14 obtained by the method of the embodiment and Comparative Sample 15.

### DETAILED DESCRIPTION

Hereinafter, embodiments will be described with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

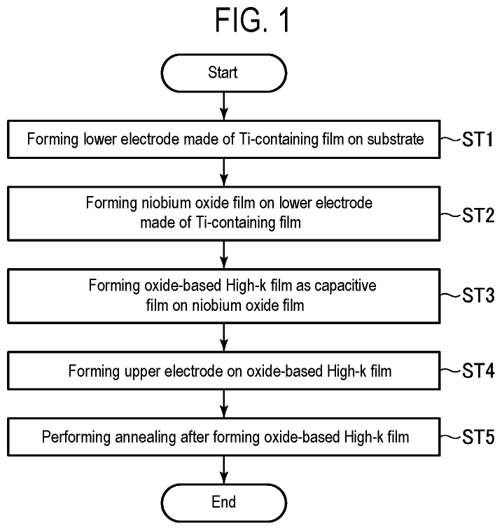

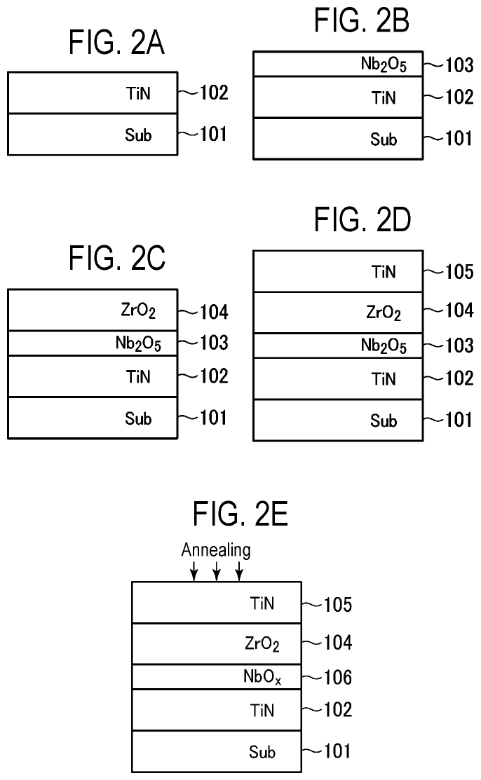

FIG. 1 is a flowchart illustrating a semiconductor device manufacturing method according to an embodiment, and FIGS. 2A to 2E are cross-sectional process views of the method.

In the present embodiment, first, a lower electrode 102 made of a Ti-containing film is formed on a substrate 101 (step ST1, FIG. 2A). The substrate 101 is not particularly limited, but a semiconductor substrate, for example, a Si substrate is exemplified. The lower electrode 102 made of a Ti-containing film may be a TiN film. In addition to the TiN film, a TiSiN film, a TiAlN film, or a TiMeN (Me: transition metal) film may also be used as the lower electrode 102. The lower electrode 102 made of a Ti-containing film may be formed by CVD, ALD, or PVD (sputtering).

Next, a niobium oxide film 103 is formed on the lower electrode 102 made of a Ti-containing film (step ST2, FIG. 2B). The niobium oxide film 103 may be formed by ALD, CVD, or PVD (sputtering). The niobium oxide film 103 may be Nb₂O₅. A film thickness of the niobium oxide film 103 may be in a range of 0.3 nm to 5 nm.

Next, an oxide-based high-dielectric-constant film (oxide-based high-k film) 104 is formed as a capacitive film on the niobium oxide film 103 (step ST3, FIG. 2C). A ZrO₂ film or HfO₂ film may be suitably used as the oxide-based high-k film 104. Further, other high dielectric constant oxides such as TiOₓ, TaOₓ, STO, BTO, and HfZrOₓ may be used. The oxide-based high-k film 104 may be formed by ALD, CVD, or PVD (sputtering), but ALD or CVD, especially ALD, is suitable. When forming the oxide-based high-k film 104 by ALD or CVD, a raw material gas containing metal elements constituting the oxides, and an oxidizing agent, for example, an ozone (O₃) gas, is used.

Next, an upper electrode 105 is formed on the oxide-based high-k film 104 (step ST4, FIG. 2D). The upper electrode 105 may be a TiN film. In addition to the TiN film, a TiSiN film, a TiAlN film, a TiMeN (Me: transition metal) film, a W film, a Mo film, or a Ru film may also be used as the upper electrode 105. The upper electrode 105 may be formed by CVD, ALD, or PVD (sputtering).

After forming the oxide-based high-k film 104, annealing is performed (step ST5, FIG. 2E). Through the formation of the oxide-based high-k film 104 in step ST3, the formation of the upper electrode 105 in step ST4, and the annealing in step ST5, the niobium oxide film is modified into a low-oxidation-number niobium oxide film that is primarily made of a niobium oxide with an oxidation number lower than Nb₂O₅.

That is, after being formed in step ST2, the niobium oxide film 103 is changed in oxidation number (valence) through the formation of the oxide-based high-k film 104 in step ST3, the formation of the upper electrode 105 in step ST4, and the annealing in step ST5. As a result, the niobium oxide film 103 is modified into a low-oxidation-number niobium oxide film (NbOₓ film) 106.

The annealing in step ST5 may be performed simultaneously with annealing for crystallization of the oxide-based high-k film 104. Further, in a case where heating is involved when forming the upper electrode 105, this annealing may be performed using heat generated during that heating. Alternatively, this annealing may be performed before or after forming the upper electrode 105. An annealing temperature may be in a range of 250 degrees C. to 600 degrees C. Further, an annealing time may be 120 minutes or less. A reducing atmosphere may be used as an atmosphere during annealing. For example, the annealing atmosphere may be a reducing atmosphere containing a 1% to 100% of H₂ gas. A film thickness of the low-oxidation-number niobium oxide film 106 obtained after annealing may be in a range of 0.3 nm to 5 nm, like the film thickness of the niobium oxide film 103. The low-oxidation-number niobium oxide film (NbOₓ film) 106 may contain a trace amount of metal element constituting the oxide-based high-k film 104.

A semiconductor device manufactured as described above is used as a capacitor, typically a DRAM capacitor and, as illustrated in FIG. 2E, includes the substrate 101, the lower electrode 102 made of a Ti-containing film, the oxide-based high-k film 104 serving as a capacitive film, the low-oxidation-number niobium oxide film (NbOₓ film) 106, and the upper electrode 105. The lower electrode 102 made of a Ti-containing film is formed on the substrate 101, and the low-oxidation-number niobium oxide film (NbOₓ film) 106 is provided between the lower electrode 102 and the oxide-based high-k film 104.

In the present embodiment, the low-oxidation-number niobium oxide film (NbOₓ film) 106 functions as an oxygen barrier and is capable of preventing formation of an interface TiO₂ film due to oxidation of the lower electrode 102 made of a Ti-containing film during the formation of the oxide-based high-k film 104. Further, a niobium oxide (NbOₓ, x<2.5) with an oxidation number lower than Nb₂O₅ exhibits conductivity and does not cause an increase in CET (Capacitance Equivalent Thickness) due to an increase in dielectric constant. For this reason, it is possible to implement a reduction in the CET of the capacitor that uses an oxide-based high-k film as a capacitive film, and to ultimately increase the capacitance of the capacitor.

Hereinafter, detailed description will be given.

In recent years, there has been a further advancement in the integration and speed enhancement of LSIs. This has led to a growing miniaturization in the design rules of semiconductor elements that make up LSIs. Consequently, there has been a trend toward a reduction in the capacitance of capacitors used in, for example, DRAM, thereby resulting in a demand for increasing the capacitance of capacitors. As mentioned in Patent Document 1, in a capacitor with a single layer of high-k dielectric ZrO₂ film between upper and lower electrodes, a reduction in CET achieved by thinning the ZrO₂ film may increase the capacitance of the capacitor. However, when using a Ti-containing film such as a TiN film which has been widely used as the lower electrode in the related art, there is a case during the formation of the oxide-based high-k film where the lower electrode is oxidized in the formation of a TiO₂ film. In particular, when forming the oxide-based high-k film by ALD, the use of an O₃ gas as an oxidizing agent may lead to a thicker TiO₂ film, which in turn increases CET. On the other hand, Patent Document 2 discloses a capacitor having a plurality of dielectric films but does not consider the issue of suppressing an increase in CET due to a TiO₂ film when using a Ti-containing film as the lower electrode.

Therefore, in the present embodiment, the niobium oxide film 103 is formed on the lower electrode 102 made of a Ti-containing film, the oxide-based high-k film 104 is formed on the niobium oxide film 103, and then annealing is performed to modify the niobium oxide film 103 into the low-oxidation-number niobium oxide film 106 primarily made of a niobium oxide (NbOₓ, x<2.5) with an oxidation number lower than Nb₂O₅.

The low-oxidation-number niobium oxide film (NbOₓ film) 106 functions as a barrier layer for oxygen from the oxide-based high-k film 104 to the lower electrode 102, thus suppressing the formation of an interface TiO₂ film. This film itself does not contribute to an increase in CET because it is conductive.

In other words, Nb₂O₅, which is an oxide with the highest oxidation number among niobium oxides, has a band gap of 1.6 eV to 2.6 eV (reference value) and is an insulating film. In contrast, if the oxidation number (NbOₓ, x<2.5) becomes lower than Nb₂O₅, the band gap is reduced, thereby resulting in conductivity. For example, the band gap of NbO₂ (x=2) is in a range of 0.3 eV to 0.4 eV (reference value) and exhibits conductivity.

As such, in the present embodiment, in the capacitor that uses the Ti-containing film as the lower electrode and the oxide-based high-k film as the capacitive film, the presence of the NbOₓ film (x<2.5) as an oxygen barrier between the lower electrode and the oxide-based high-k film suppresses the formation of an interface TiO₂ film. Further, the NbOₓ film itself is conductive and thus, does not contribute to an increase in CET. For this reason, it is possible to implement a reduction in the CET of the capacitor that uses the Ti-containing film as the lower electrode and the oxide-based high-k film as the capacitive film.

The semiconductor device (capacitor) according to the present embodiment was actually prepared to determine characteristics thereof. Here, a niobium oxide film (Nb₂O₅ film) of a thickness of 1 nm was formed on a lower electrode made of a TiN film formed on a Si substrate, and a ZrO₂ film of a thickness of 5 nm was formed on the niobium oxide film. After the formation of the ZrO₂ film, an upper electrode made of a TiN film was formed, and annealing was performed at 400 degrees C. for 10 minutes using a forming gas of 4% H₂ gas and 96% N₂ gas to obtain a sample where the niobium oxide film was modified into a low-oxidation-number niobium oxide film (NbOₓ film) primarily made of NbOₓ (x<2.5) (Sample 1). In addition, a film thickness of the NbOₓ film of Sample 1 was 1 nm, which is almost the same as that of the Nb₂O₅ film. Further, a sample for comparison was obtained by forming, on a lower electrode made of a TiN film formed on a Si substrate, a ZrO₂ film of a thickness of 5 nm and an upper electrode made of a TiN film as in Sample 1 without forming a niobium oxide film, and then performing annealing similarly (Comparative Sample 2).

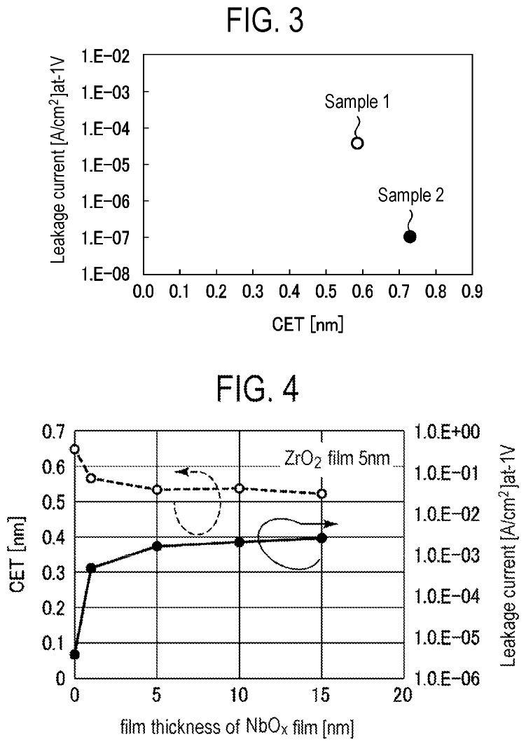

The results of CET and leakage current for these Samples 1 and 2 were obtained. The results are illustrated in FIG. 3. As illustrated in FIG. 3, Sample 1 obtained by the method of the present embodiment exhibited a reduction in CET of approximately 20% compared to Comparative Sample 2. While Sample 1 had a slightly higher leakage current than Sample 2, the overall performance of Sample 1 was within a comparable range when considering a reduction in CET.

Next, samples were prepared by forming niobium oxide films (Nb₂O₅ films) of thicknesses of 1 nm, 5 nm, 10 nm, and 15 nm on a lower electrode made of a TiN film formed on a Si substrate, forming, on the niobium oxide films, a ZrO₂ film of a thickness of 5 nm and an upper electrode made of a TiN film as in Sample 1, and then performing annealing (Samples 11, 12, 13, and 14). In addition, the film thicknesses of the NbOₓ films of Samples 11, 12, 13, and 14 after modification were 1 nm, 5 nm, 10 nm, and 15 nm, which are almost the same as those of the Nb₂O₅ films. Further, a sample was also prepared by forming, on a lower electrode made of a TiN film formed on a Si substrate, a ZrO film of a thickness of 5 nm and an upper electrode made of a TiN film without forming a niobium oxide film, and then performing annealing similarly (Sample 15). The results of CET and leakage currents for these Samples 11 to 15 were obtained.

FIG. 4 illustrates a relationship between the film thickness of the NbOₓ film and CET as well as the leakage current based on the values of CET and leakage currents for Samples 11 to 15. As illustrated in this drawing, it can be seen that CET is almost constant even if the film thickness of the NbOₓ film is increased. This is indicative of the conductivity of the NbOₓ film. Further, it can be seen that not only CET but also the leakage currents are almost constant with respect to the thickness of the NbOₓ film.

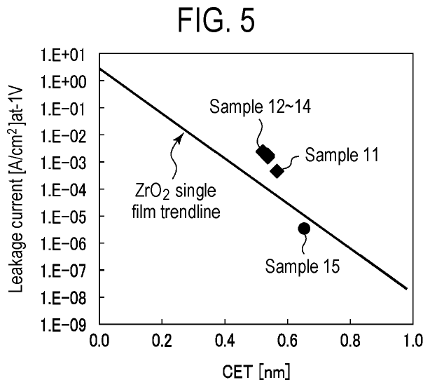

FIG. 5 is a view illustrating a relationship between CET and the leakage currents for Samples 11 to 15. A straight line in FIG. 5 represents a trendline for a capacitor with a single layer of ZrO₂ film in the related art. As illustrated in FIG. 5, compared to Sample 15 where there is no NbOₓ film, it can be seen that Samples 11 to 14, where the NbOₓ film was formed, exhibited a reduction in CET of 20% or more. Further, while Samples 11 to 14 had slightly higher leakage currents than the trendline, the overall performance thereof was within a comparable range.

The above demonstrates that the presence of the NbOX film between the lower electrode made of a TiN film and the ZrO₂ film as the capacitive film may achieve a significant reduction in CET without substantially increasing the leakage current.

According to the present disclosure, there are provided a semiconductor device manufacturing method and a semiconductor device which are capable of implementing a reduction in CET of a capacitor using an oxide-based high-dielectric-constant film.

Although the embodiments have been described above, the embodiments disclosed herein should be considered to be exemplary and not restrictive in all respects. The above embodiments may be omitted, replaced, or modified in various ways without departing from the scope and spirit of the appended claims.

What is claimed is:

1. A method of manufacturing a semiconductor device, the method comprising:
forming a lower electrode made of a Ti-containing film on a substrate;
forming a niobium oxide film on the lower electrode;
forming an oxide-based high-dielectric-constant film on the niobium oxide film;
forming an upper electrode on the oxide-based high-dielectric-constant film; and
performing annealing,
wherein, through the forming of the oxide-based high-dielectric-constant film, the forming of the upper electrode, and the performing of the annealing, the niobium oxide film is modified into a low-oxidation-number niobium oxide film that is primarily made of a niobium oxide with an oxidation number lower than Nb₂O₅.

2. The method of claim 1, wherein the Ti-containing film constituting the lower electrode is a TiN film.

3. The method of claim 1, wherein the oxide-based high-dielectric-constant film is one of a ZrO₂ film and a HfO₂ film.

4. The method of claim 1, wherein the oxide-based high-dielectric-constant film is formed by ALD or CVD using a raw material gas and an oxidizing agent.

5. The method of claim 4, wherein the oxidizing agent is an O₃ gas.

6. The method of claim 1, wherein the low-oxidation-number niobium oxide film has a film thickness in a range of 0.3 nm to 5 nm.

7. The method of claim 1, wherein the annealing is performed under a reducing atmosphere.

8. The method of claim 1, wherein the semiconductor device is a DRAM capacitor.

9. The method of claim 5, wherein the low-oxidation-number niobium oxide film has a film thickness in a range of 0.3 nm to 5 nm.

10. The method of claim 5, wherein the annealing is performed under a reducing atmosphere.

11. The method of claim 5, wherein the semiconductor device is a DRAM capacitor.

12. A semiconductor device comprising:
a substrate;
a lower electrode made of a Ti-containing film and formed on the substrate;
an oxide-based high-dielectric-constant film which is a capacitive film;
a low-oxidation-number niobium oxide film provided between the lower electrode and the oxide-based high-dielectric-constant film and primarily made of a niobium oxide with an oxidation number lower than Nb₂O₅; and
an upper electrode formed on the oxide-based high-dielectric-constant film.

13. The semiconductor device of claim 12, wherein the Ti-containing film constituting the lower electrode is a TiN film.

14. The semiconductor device of claim 12, wherein the oxide-based high-dielectric-constant film is one of a ZrO₂ film and a HfO₂ film.

15. The semiconductor device of claim 12, wherein the semiconductor device is used as a DRAM capacitor.

16. The semiconductor device of claim 14, wherein the semiconductor device is used as a DRAM capacitor.
